(19) United States
(12) Patent Application Publication
(10) Pub. No.: US 2026/0353716 A1
(43) Pub. Date: Nov. 5, 2026

(54) Implant for Cell Size Reduction in Super Junction Device

(71) Applicant: Applied Materials, Inc., Santa Clara, CA (US)

(72) Inventors: Nan Zheng, Malden, MA (US); Supakit Charnvanichborikarn, Gloucester, MA (US); Hans-Joachim Gossmann, Summit, NJ (US); Wei Zou, Lexington, MA (US)

(73) Assignee: Applied Materials, Inc., Santa Clara, CA (US)

(21) Appl. No.: 19/324,783

(22) Filed: Sep. 10, 2025

Related U.S. Application Data
(60) Provisional application No. 63/799,094, filed on May 2, 2025.

(51) Int. Cl. H10D 62/00; H10D 30/01; H10D 30/66; H10D 62/10

(52) U.S. Cl. CPC H10D 62/054; H10D 30/0291; H10D 30/66; H10D 62/111

(57) ABSTRACT

Disclosed are approaches for forming a super junction transistor. One approach may include patterning a first plurality of openings through a first masking layer, wherein the first masking layer is formed over a device stack, and wherein the device stack includes an epitaxial layer over a substrate. The method may further include performing a first implant through the openings to form a first plurality of dopant cores in the epitaxial layer, wherein the first implant comprises directing p-type ions to an exposed epitaxial layer. The method may further include patterning a second plurality of openings through a second masking layer formed over the epitaxial layer. The method may further include performing a second implant through the second plurality of openings of to form a second plurality of dopant cores in the epitaxial layer, wherein the second implant includes directing n-type ions to the exposed epitaxial layer.

### CROSS-REFERENCE TO RELATED APPLICATIONS

The present application claims priority to U.S. Provisional Patent Application No. 63/799,094, filed May 2, 2025, and entitled “Implant for Cell Size Reduction in Super Junction Device,” and incorporates its disclosure herein by reference in its entirety.

### FIELD OF THE DISCLOSURE

The present disclosure relates to semiconductor devices and, more particularly, to methods of forming super junction transistors with smaller lateral diffusion distances and reduced pillar sizes.

### BACKGROUND OF THE DISCLOSURE

The intrinsic physical properties of silicon is a limiting factor for high voltage power applications. For high voltage power devices, the resistance from the drift layer is highly influential. For conventional planar MOSFET (Metal-Oxide-Semiconductor Field-Effect Transistor) devices, a large part of the drift region remains neutral (undepleted) without any gradient. Therefore, the Rdrift is large to achieve a certain level of breakdown voltage. However, with super junction MOSFET structures, the potential is rearranged and drags towards the initially undepleted sides. A more uniform distribution is achieved. Super junction enhances the breakdown capability of Si power device without increasing the Rdrift.

Multi-epitaxy-multi-implant (MEMI) is the mainstream fabrication method for the commercially available silicon super junction device. It uses the masked ion implantation, growth of epitaxial layers and the diffusion to form the pillar structure. The advantage of MEMI is its capability to adjust the doping levels of both p-and n-regions in each layer. The method has hence more degrees of freedom to balance the requirement from many design parameters of the super junction device. However, as future generations of super junction devices continue to scale smaller, the cell pitch reduction is critical. Current MEMI methods utilizing B and P dopants will meet the dopant compensation issue when reducing the cell pitch.

It is with respect to these and other drawbacks of the current art that the present disclosure is provided.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In some embodiments, a method may include patterning a first plurality of openings through a first masking layer, wherein the first masking layer is formed over a device stack, and wherein the device stack comprises an epitaxial layer over a substrate. The method may further include performing a first implant through the first plurality of openings to form a first plurality of dopant cores in the epitaxial layer, wherein the first implant comprises directing p-type ions to an exposed upper surface of the epitaxial layer. The method may further include patterning a second plurality of openings through a second masking layer, wherein the second masking layer is formed over the epitaxial layer. The method may further include performing a second implant through the second plurality of openings to form a second plurality of dopant cores in the epitaxial layer, wherein the second implant comprises directing n-type ions to the exposed upper surface of the epitaxial layer.

In some embodiments, a super junction metal-oxide-semiconductor field-effect transistor may include a stack of p-type dopant cores adjacent a stack of n-type dopant cores, wherein the stack of p-type dopant cores and the stack of n-type dopant cores are formed in an epitaxial material, and wherein a first width of the stack of p-type dopant cores is greater than a second width of the stack of n-type dopant cores.

In some embodiments, a method of forming a super junction metal-oxide-semiconductor field-effect transistor may include patterning a first plurality of openings through a first masking layer, wherein the first masking layer is formed over a device stack, and wherein the device stack comprises an epitaxial layer over a substrate. The method may further include performing a first implant through the first plurality of openings to form a first plurality of dopant cores in the epitaxial layer, wherein the first implant comprises directing p-type ions to an exposed upper surface of the epitaxial layer, and patterning a second plurality of openings through a second masking layer, wherein the second masking layer is formed over the epitaxial layer. The method may further include performing a second implant through the second plurality of openings of to form a second plurality of dopant cores in the epitaxial layer, wherein the second implant comprises directing arsenic ions to the exposed upper surface of the epitaxial layer.

### BRIEF DESCRIPTION OF THE DRAWINGS

The accompanying drawings illustrate exemplary approaches of the disclosure, including the practical application of the principles thereof, as follows:

FIGS. 1-10 illustrate side cross-sectional views of a portion of a device, such as a MOSFET, during formation/patterning, according to embodiments of the present disclosure;

FIG. 11 illustrates a schematic diagram of a processing apparatus according to embodiments of the present disclosure;

FIG. 12 illustrates a diagram of a cluster tool according to embodiments of the present disclosure; and

FIG. 13 is an example system operable to provide pulsed RF-excited continuous plasma doping according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods, devices, and systems in accordance with the present disclosure will now be described more fully hereinafter with reference to the accompanying drawings, where various embodiments are shown. The methods, devices, and systems may be embodied in many different forms and are not to be construed as being limited to the embodiments set forth herein. Instead, these embodiments are provided so the disclosure will be thorough and complete, and will fully convey the scope of the methods to those skilled in the art.

To address the deficiencies of the prior art described above, disclosed herein are approaches for forming a super junction MOSFET wherein arsenic (As) is used as the n-type dopant. Arsenic has a lower diffusivity (about ~25% of P at 1000 deg C) to enable smaller lateral diffusion distance and the smaller n-pillar size. Boron (B) and arsenic are implanted into an epitaxial layer with designed width and dopant concentration. Under the diffusion with the same thermal budget, arsenic dopants diffuse less distance due to lower diffusivity and form a narrower n-pillar. Cell pitch may be reduced accordingly.

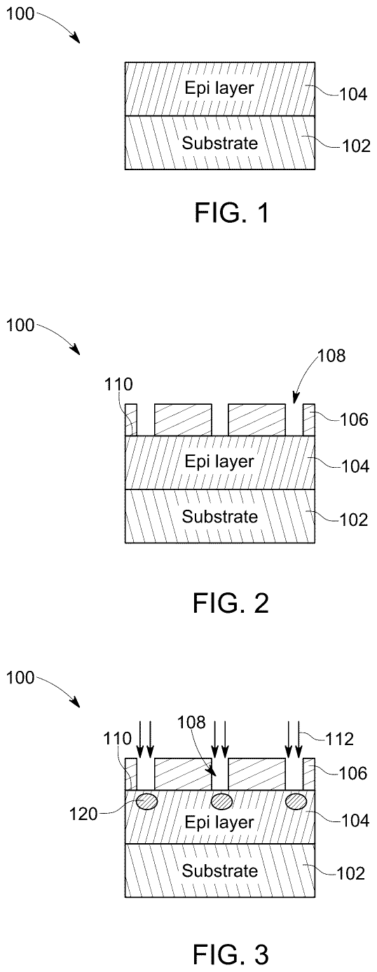

FIG. 1 is a side cross-sectional view of a portion of a semiconductor device (hereinafter “device”) 100, such as a super junction MOSFET, at one stage of processing, according to embodiments of the present disclosure. As shown, the device 100 may include a substrate 102 and an epitaxial layer (hereinafter “epi layer”) 104 formed over the substrate 102, which may be silicon.

FIG. 2 demonstrates a first masking layer 106 formed over the epi layer 104. More specifically, the first masking layer 106 may be deposited and then patterned (e.g., etched) to form a plurality of first openings 108 therein. The openings 108 may be formed selective to an upper surface 110 of the epi layer 104 to expose select portions of the epi layer 104.

FIG. 3 demonstrates performing a first implant 112 through the first plurality of openings 108 to form a plurality of first of dopant cores 120 in the epitaxial layer 104 of the device 100. In some embodiments, the first implant 112 includes directing p-type ions, such as boron (B⁺), to the exposed upper surface 110 of the epitaxial layer 104. In other embodiments, other low-diffusing p-type dopants may be used, such as gallium (Ga) or indium (In). As used herein, the first dopant cores 120 may each be layers or areas of increased dopant concentration formed in the epi layer 104. Although shown as having a substantially oval or elliptical shape/profile, it will be appreciated that other shapes, sizes, and depths are possible in alternative embodiments, e.g., based on parameters of the first implant 112, such as implant energy and implant duration. Although non-limiting, the first implant 112 may be a plasma-based doping (PLAD) or beamline implant.

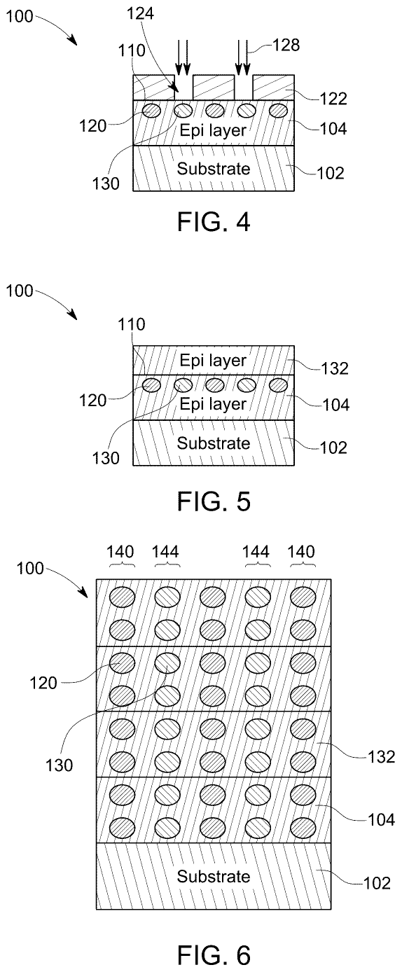

FIG. 4 demonstrates a second masking layer 122 formed over the epi layer 104. More specifically, the second masking layer 122 may be deposited and then patterned (e.g., etched) to form a plurality of second openings 124 therein. The second openings 124 may be formed selective to the upper surface 110 of the epi layer 104 to expose select portions of the epi layer 104.

A second implant 128 may then be delivered through the plurality of second openings 124 to form a plurality of second dopant cores 130 in the epitaxial layer 104 of the device 100. The second dopant cores 130 are formed adjacent/in-between the first dopant cores 120. In some embodiments, the second implant 128 includes directing arsenic ions to the exposed upper surface 110 of the epitaxial layer 104. Although non-limiting, the second implant 128 may be a PLAD or beamline implant.

As used herein, the second dopant cores 130 may each be layers or areas of increased dopant concentration formed in the epi layer 104. Although shown as having a substantially oval or elliptical shape/profile, it will be appreciated that other shapes, sizes, and depths are possible in alternative embodiments for the second dopant cores 130, e.g., based on parameters of the second implant 128, such as implant energy and implant duration.

As shown in FIG. 5, a second epi layer 132 may then be formed over the device 100, including over the first and second dopant cores 120, 130. The second epi layer 132 may be epitaxially grown to a desired thickness or height, which may be adjusted to fit the diffusion length caused by subsequent dopant implants.

As shown in FIG. 6, patterning may continue by performing a series of masking and implantation steps, similar to those shown in FIGS. 2-5 and described herein, to form a stack of p-type dopant cores 140 adjacent a stack of arsenic dopant cores 144. As shown, the stack of p-type dopant cores 140 and the stack of arsenic dopant cores 144 are formed in an epi material, which may be deposited or grown atop the stack following formation of each layer of first and second dopant cores 120, 130. The stack of p-type dopant cores 140 and the stack of arsenic dopant cores 144 are generally oriented vertically, as adjacent columns or pillars. Each layer in the stack of p-type dopant cores 140 and the stack of arsenic dopant cores 144 may be separated from an adjacent layer (e.g., above or below it) by a portion of the epi material.

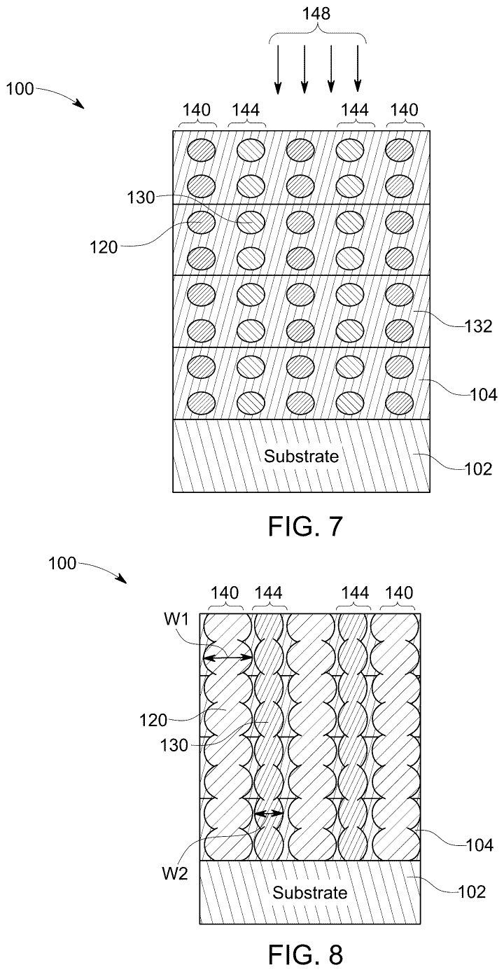

A thermal treatment 148 may then be performed to the device, as shown in FIG. 7. In some embodiments, the thermal treatment 148 may be an anneal performed at a temperature greater than 900 deg C, which causes diffusion of the stack of p-type dopant cores 140 and diffusion of the stack of arsenic dopant cores 144, as shown in FIG. 8. Said differently, the thermal treatment 148 causes expansion of the first dopant cores 120 until the first dopant cores 120 connect or join. Similarly, the thermal treatment 148 causes expansion of the second dopant cores 130 until the second dopant cores 130 connect or join. The annealing condition can be tuned to match the designed diffusion distance. In some embodiments, the diffusion stops before the stack of p-type dopant cores 140 and the stack of arsenic dopant cores 144 overlap laterally with one another.

As demonstrated in FIG. 8, following the diffusion process, a first width (W1) of the stack of p-type dopant cores 140 is greater than a second width (W2) of the stack of arsenic dopant cores 144. Use of arsenic in the second implant 128 reduces diffusion, thus permitting increased device scaling. In other embodiments, in which In or Ga is introduced as the p-type dopant to perform a similar function to As, W2 may or may not be smaller than W1. In any case, introduction of As, In, or Ga reduces diffusion, thus permitting device scaling.

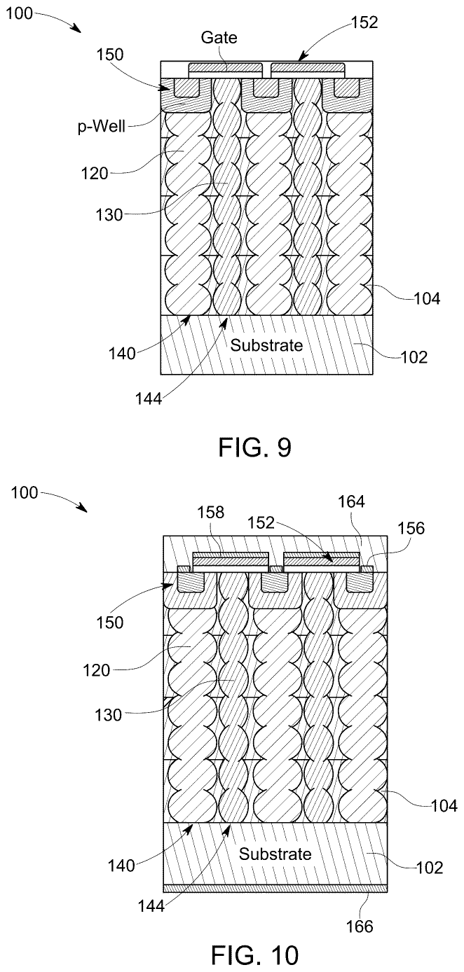

Processing of the super junction MOSFET may then continue, as demonstrated in FIG. 9. For example, plurality of gate structures 152 and a plurality of well structures 150 may be formed over the stack of p-type dopant cores 140 and the stack of arsenic dopant cores 144.

Processing may continue in FIG. 10, which demonstrates contact and passivation layer formation. More specifically, a plurality of source contacts 156 and gate contacts 158 may be formed adjacent the plurality of gate structures 152 and the plurality of well structures 150, and a passivation layer 164 may be formed over the source contacts 156 and the gate contacts 158. As further shown, a plurality of drain contacts 166 may be formed beneath the substrate 102.

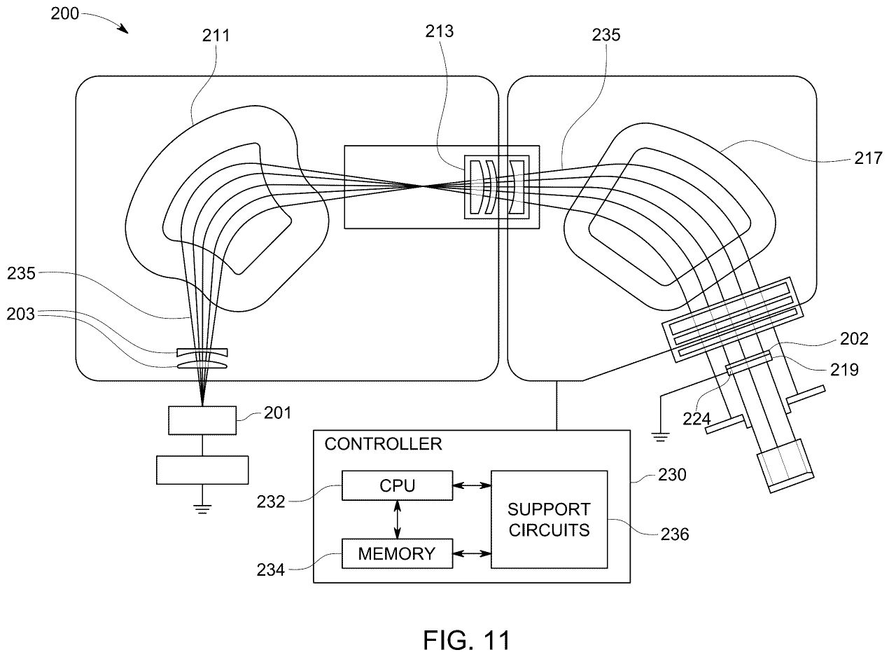

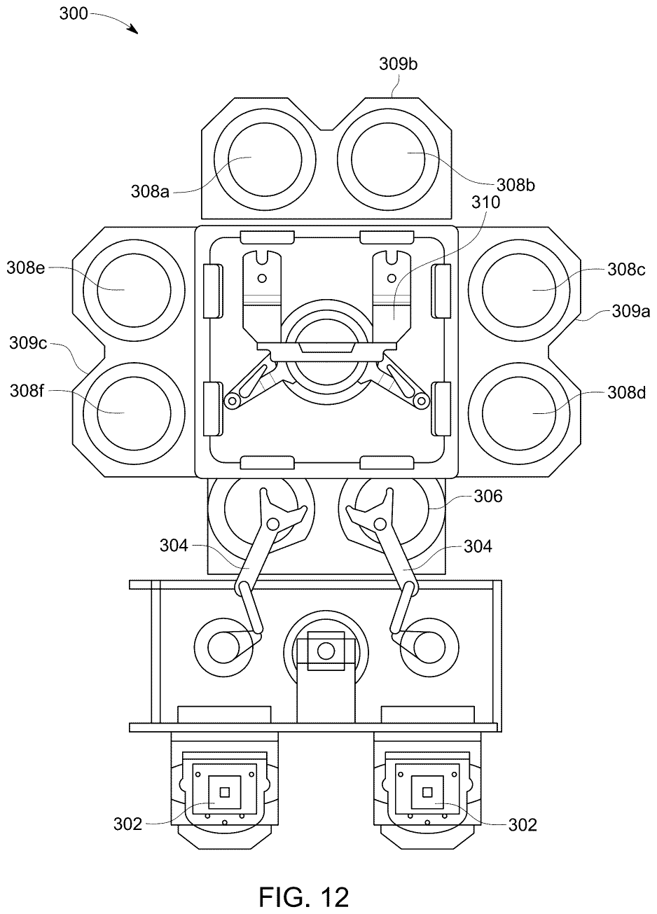

FIG. 11 illustrates a schematic diagram of a processing apparatus 200 useful to perform processes described herein. The processing apparatus 200 may include an ion source 201 for generating ions. For example, the ion source 201 may provide an ion treatment, such as the first implant 112 demonstrated in FIG. 3 or the second implant 128 shown in FIG. 4.

The processing apparatus 200 may also include a series of beam-line components. Examples of beam-line components may include extraction electrodes 203, a magnetic mass analyzer 211, a plurality of lenses 213, and a beam parallelizer 217. The processing apparatus 200 may also include a platen 219 for supporting a substrate 202 to be processed. In some embodiments, the platen 219 may be heated using an external or embedded heating element 224, such as a resistive heater, or may be heated using radiant heat, such as heating lamps disposed above or below the platen 219. In other embodiments, the heating element may additionally, or alternatively, be located in a load lock chamber or a separate pre-heat chamber to pre-heat the wafer 202 before it reaches the platen 219. Even with a pre-heat, the platen 219 may include the internal heating element 224. The substrate 202 may be the same as the substrate 102 described above. The substrate 202 may be moved in one or more dimensions (e.g. translate, rotate, tilt, etc.) by a component sometimes referred to as a rotating platen or “roplat” (not shown). It is also contemplated that the processing apparatus 200 may be configured to perform heated treatment processes to provide for improved control of treatment characteristics, such as the ion trajectory and ion treatment energy utilized to treat the substrate 202.

In operation, ions of the desired species, for example, dopant ions, are generated and extracted from the ion source 201. Thereafter, the extracted ions 235 travel in a beam-like state along the beam-line components and may be directed to be incident on the substrate 202. Similar to a series of optical lenses that manipulate a light beam, the beam-line components manipulate the extracted ions 235 along the ion beam. In such a manner, the extracted ions 235 are manipulated by the beam-line components while the extracted ions 235 are directed toward the substrate 202. It is contemplated that the apparatus 200 may provide for improved mass selection to process with desired ions while reducing the probability of undesirable ions (impurities) being incident on the substrate 202.

In some embodiments, the processing apparatus 200 can be controlled by a processor-based system controller such as controller 230. For example, the controller 230 may be configured to control beam-line components and processing parameters associated with beam-line ion treatments. The controller 230 may include a programmable central processing unit (CPU) 232 that is operable with a memory 234 and a mass storage device, an input control unit, and a display unit (not shown), such as power supplies, clocks, cache, input/output (I/O) circuits, and the like, coupled to the various components of the processing apparatus 200 to facilitate control of the substrate processing. The controller 230 also includes hardware for monitoring substrate processing through sensors in the processing apparatus 200, including sensors monitoring the substrate position and sensors configured to receive feedback from and control a heating apparatus coupled to the processing apparatus 200. Other sensors that measure system parameters such as substrate temperature and the like, may also provide information to the controller 230.

To facilitate control of the processing apparatus 200 described above, the CPU 232 may be one of any form of general-purpose computer processor that can be used in an industrial setting, such as a programmable logic controller (PLC), for controlling various chambers and sub-processors. The memory 234 is coupled to the CPU 232 and the memory 234 is non-transitory and may be one or more of readily available memory such as random access memory (RAM), read only memory (ROM), floppy disk drive, hard disk, or any other form of digital storage, local or remote. Support circuits 236 may be coupled to the CPU 232 for supporting the processor in a conventional manner. Ion processing and other processes are generally stored in the memory 234, typically as a software routine. The software routine may also be stored and/or executed by a second CPU (not shown) that is remotely located from the hardware being controlled by the CPU 232.

The memory 234 is in the form of computer-readable storage media that contains instructions, that when executed by the CPU 232, facilitates the operation of the apparatus 200. The instructions in the memory 234 are in the form of a program product such as a program that implements the method of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

FIG. 12 illustrates a top plan view of one embodiment of another processing system 300 including a plurality of chambers according to some embodiments. As shown, a pair of front opening unified pods 302 supply substrates of a variety of sizes that are received by robotic arms 304 and placed into a low-pressure holding area 306 before being placed into one of the substrate processing chambers 308a-f, positioned in tandem sections 309a-c. A second robotic arm 310 may be used to transport the substrate wafers from the holding area 306 to the substrate processing chambers 308a-f and back.

The substrate processing chambers 308a-f may include one or more system components for depositing, treating, growing, annealing, curing, implanting, and/or etching the substrate and/or a material layer on the substrate or wafer. In one configuration, one or more of the processing chambers, for example 308a, may be used to implant or otherwise treat the substrate and/or the material layers formed atop the substrate using an ion-based treatment from processing apparatus 200, which may be present within the processing chamber 308a.

Any one or more of the processes described may be carried out in additional chambers separated from the fabrication system shown in different embodiments. It will be appreciated that additional configurations of deposition, ion treating, growing, etching, annealing, and curing chambers for substrates and material layers are contemplated by the processing system 300. Additionally, any number of other processing systems may be utilized with the present technology, which may incorporate chambers for performing any of the specific operations. In some embodiments, chamber systems which may provide access to multiple processing chambers while maintaining a vacuum environment in various sections, such as the noted holding and transfer areas, may allow operations to be performed sequentially in multiple chambers while maintaining a particular vacuum environment between discrete processes.

The processing system 300, or more specifically, chambers incorporated into the processing system 300 or other processing systems, may be used to produce structures according to some embodiments of the present disclosure.

In some embodiments, one of processing chambers 308a-f may include a gas cluster ion source for producing a gas cluster ion beam (GCIB) or a gas cluster beam (GCB). In some embodiments, the gas cluster ion source may provide an ion treatment, such as the first implant 112 demonstrated in FIG. 3 and/or the second implant 128 shown in FIG. 4.

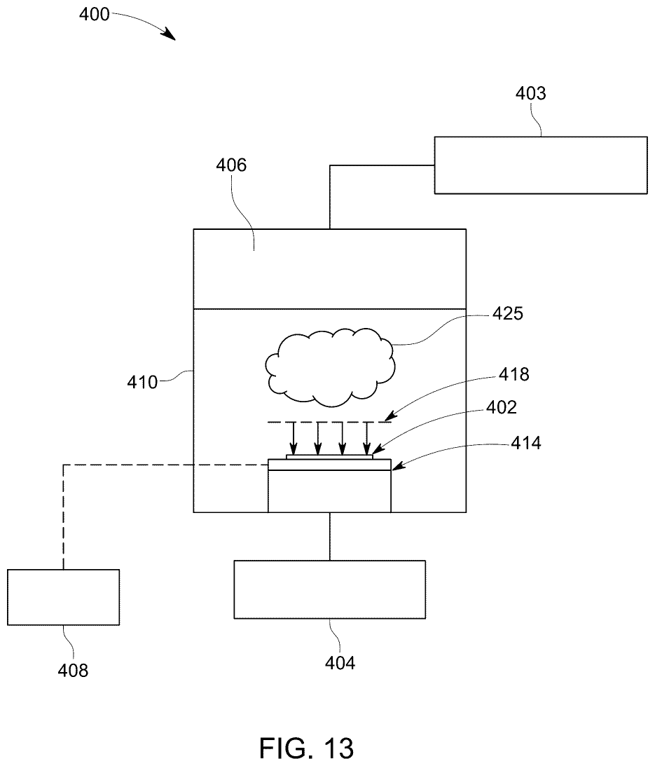

Referring to FIG. 13, an example system 400 (e.g., a PLAD system) operable to provide pulsed RF-excited continuous plasma doping will be described. System 400 may be useful to perform processes described herein, such as one or more plasma treatments/processes on a wafer/substrate 402. The system 400 may be present in one of the processing chambers 308a-f of FIG. 12.

As shown, the system 400 may include a plasma power supply 403, a voltage pulse power supply 404, an RF coil array 406, and a dosimeter 408. Within a plasma chamber 410 is a wafer/substrate 402, which may be the same or similar to the substrate base 102 described above, supported by a platen/pedestal 414. A plasma sheath 418 may be formed above the substrate 402. A temperature of the platen/pedestal 414 may be elevated (e.g., to 500 °C or greater) during plasma doping. The dosimeter 408 may be a Faraday dosimeter or other type of sensor that directly measures the dose of ions received by the substrate 402. Although non-limiting, the dosimeter can be located on the pedestal 414, proximate to the substrate 402.

During processing, the plasma power supply 403 and the RF coil array 406 deliver radio frequency excitation to generate a plasma 425 when gaseous species are delivered into the plasma chamber 410. For example, the plasma power supply 403 may be an RF powered inductively coupled power source to generate inductively coupled plasma 425, as known in the art. Gaseous species may be delivered from one or more gas sources (not separately shown) to generate ions of any suitable species, such as boron.

The voltage pulse power supply 404 may generate a bias voltage between the substrate 402 and the plasma chamber 410. As such, when the voltage pulse power supply 404 generates a voltage between the plasma chamber 410 and the substrate 402, a similar, but slightly larger, voltage difference is generated between the plasma 425 and the substrate 402. In one non-limiting example, a 5000 V (5 kV) voltage difference established between the plasma chamber 410 and the substrate 402 (or, equivalently, pedestal 414) may generate a voltage difference of approximately 5005 V to 5030 V between the plasma 425 and the substrate 402.

In some embodiments, the voltage pulse power supply 404 may generate a bias voltage as a pulsed voltage signal, wherein the pulsed voltage signal is applied in a repetitive and regular manner, to generate a pulse routine comprising a plurality of extraction voltage pulses. For example, a pulse routine may apply voltage pulses of 500 V magnitude, 1000 V magnitude, 2000 V magnitude, 5000 V magnitude, or 10,000 V magnitude in various non-limiting embodiments. The system 400 may further include a controller (not shown), to control the pulsing routine applied to the substrate 402, in order to provide the PLAD treatment.

According to various embodiments, the plasma 425 may be formed at least in part of ions that constitute a species capable of performing the first implant 112 and/or the second implant 128, as described herein. When the plasma 425 is present in the plasma chamber 410, the controller may generate a signal for the voltage pulse power supply 404 to apply a pulse routine to the substrate 402, where the pulse routine constitutes a plurality of extraction voltage pulses. As such, when the extraction voltage pulses are applied between the substrate 402 and plasma 425, ions are extracted in pulsed form from the plasma 425, generating a plurality of ion pulses that are directed to the substrate 402.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporate the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

As used herein, “depositing” and/or “deposited” may include any now known or later developed techniques appropriate for the material to be deposited including yet not limited to, for example: chemical vapor deposition (CVD), low-pressure CVD (LPCVD), and plasma-enhanced CVD (PECVD). Additional techniques may include semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), and sputtering deposition. Additional techniques may include ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method, comprising:
patterning a first plurality of openings through a first masking layer, wherein the first masking layer is formed over a device stack, and wherein the device stack comprises an epitaxial layer over a substrate;
performing a first implant through the first plurality of openings to form a first plurality of dopant cores in the epitaxial layer, wherein the first implant comprises directing p-type ions to an exposed upper surface of the epitaxial layer;
patterning a second plurality of openings through a second masking layer, wherein the second masking layer is formed over the epitaxial layer; and
performing a second implant through the second plurality of openings to form a second plurality of dopant cores in the epitaxial layer, wherein the second implant comprises directing n-type ions to the exposed upper surface of the epitaxial layer.

2. The method of claim 1, further comprising forming a second epitaxial layer over the epitaxial layer following formation of the first plurality of dopant cores and the second plurality of dopant cores.

3. The method of claim 1, further comprising performing a series of masking and implantation processes to form a stack of p-type dopant cores adjacent a stack of n-type dopant cores.

4. The method of claim 3, further comprising performing a thermal treatment following formation of the stack of p-type dopant cores and the stack of n-type dopant cores.

5. The method of claim 4, wherein the thermal treatment is an anneal process.

6. The method of claim 4, wherein the thermal treatment causes diffusion of the p-type dopant cores of the stack of p-type dopant cores and diffusion of the n-type dopant cores of the stack of n-type dopant cores.

7. The method of claim 3, wherein a first width of the stack of p-type dopant cores is greater than a second width of the stack of n-type dopant cores, and wherein the n-type dopant cores are arsenic cores.

8. The method of claim 3, further comprising forming a plurality of gate structures and a plurality of well structures over the stack of p-type dopant cores and the stack of n-type dopant cores.

9. The method of claim 8, further comprising forming a source contact and a drain contact following formation of the plurality of gate structures and the plurality of well structures.

10. The method of claim 1, wherein the p-type ions of the first implant comprises boron ions, and wherein the n-type ions of the second implant comprises arsenic ions.

11. A super junction metal-oxide-semiconductor field-effect transistor, comprising:
a stack of p-type dopant cores adjacent a stack of n-type dopant cores, wherein the stack of p-type dopant cores and the stack of n-type dopant cores are formed in an epitaxial material, and wherein a first width of the stack of p-type dopant cores is greater than a second width of the stack of n-type dopant cores.

12. The metal-oxide-semiconductor field-effect transistor of claim 11, further comprising a substrate, wherein the epitaxial material is formed over the substrate.

13. The metal-oxide-semiconductor field-effect transistor of claim 12, further comprising a plurality of gate structures and a plurality of well structures over the stack of p-type dopant cores and the stack of n-type dopant cores.

14. The metal-oxide-semiconductor field-effect transistor of claim 13, further comprising a source contact adjacent the plurality of gate structures and the plurality of well structures.

15. The metal-oxide-semiconductor field-effect transistor of claim 12, further comprising a drain contact adjacent the substrate.

16. A method of forming a super junction metal-oxide-semiconductor field-effect transistor, the method comprising:
patterning a first plurality of openings through a first masking layer, wherein the first masking layer is formed over a device stack, and wherein the device stack comprises an epitaxial layer over a substrate;
performing a first implant through the first plurality of openings to form a first plurality of dopant cores in the epitaxial layer, wherein the first implant comprises directing p-type ions to an exposed upper surface of the epitaxial layer;
patterning a second plurality of openings through a second masking layer, wherein the second masking layer is formed over the epitaxial layer; and
performing a second implant through the second plurality of openings of to form a
second plurality of dopant cores in the epitaxial layer, wherein the second implant comprises directing arsenic ions to the exposed upper surface of the epitaxial layer.

17. The method of claim 16, further comprising forming a second epitaxial layer over the epitaxial layer following formation of the first plurality of dopant cores and the second plurality of dopant cores.

18. The method of claim 16, further comprising performing a series of masking and implantation processes to form a stack of p-type dopant cores adjacent a stack of n-type dopant cores.

19. The method of claim 18, further comprising performing a thermal treatment following formation of the stack of p-type dopant cores and the stack of n-type dopant cores.

20. The method of claim 19, wherein the thermal treatment causes diffusion of the p-type dopant cores and the n-type dopant cores.
